(19) United States
(12) Patent Application Publication
(10) Pub. No.: US 2024/0427057 A1
(43) Pub. Date: Dec. 26, 2024

(54) ANTIREFLECTIVE OPTICAL ELEMENT

(71) Applicants: SAFRAN ELECTRONICS & DEFENSE, Paris (FR); CENTRE NATIONAL DE LA RECHERCHE SCIENTIFIQUE, Paris (FR); UNIVERSITE DE POITIERS, POITIERS CEDEX (FR)

(72) Inventors: Cyril DUPEYRAT, MOISSY-CRAMAYEL (FR); Fabien PAUMIER, BUXEROLLES (FR); Baptiste Simon GIROIRE, BORDEAUX (FR)

(73) Assignees: SAFRAN ELECTRONICS & DEFENSE, Paris (FR); CENTRE NATIONAL DE LA RECHERCHE SCIENTIFIQUE, Paris (FR); UNIVERSITE DE POITIERS, POITIERS CEDEX (FR)

(21) Appl. No.: 18/699,217

(22) PCT Filed: Oct. 6, 2022
(86) PCT No.: PCT/FR2022/051892

§ 371 Date: Apr. 5, 2024

(30) Foreign Application Priority Data
Oct. 13, 2021 (FR) FR2110838

(51) Int. Cl. G02B 1/11; B64D 47/00

(52) U.S. Cl. CPC G02B 1/11; B64D 47/00

(57) ABSTRACT

An optical element includes
a transparent substrate and
an intermediate coating extending over at least one main surface of the substrate. The intermediate coating has a plurality of dense thin layers which alternate in having a first index refractive index and a second refractive index, the first refractive index being greater than the second refractive index.

The optical element further includes
at least one porous layer extending over the intermediate coating, opposite the substrate. The porous layer has a third refractive index that is lower than the first and second refractive indices.

### TECHNICAL FIELD OF THE INVENTION

The invention relates to an optical element having antireflective properties. The invention also relates to an optronic device comprising at least one such optical element, as well as to an aircraft comprising at least one such optronic device. Furthermore, the invention relates to a method for manufacturing such an optical element.

### PRIOR ART

The addition of an antireflective coating on an optical element, such as a lens or a porthole, allows reducing the amount of light that is reflected when a light beam passes through the coated surface, and thus improves the transmission of light through the optical element.

This is particularly important for devices comprising several optical elements which are successively traversed by a light beam, and each comprising two surfaces traversed by said beam, such as optronic devices.

Two types of antireflective coatings are known in the state of the art, respectively based on interference and on gradient refractive index.

FIG. 1 illustrates an optical element 10 known in the state of the art, comprising a transparent substrate 12 and an antireflective coating 14 that is interference-based. Antireflective coating 14 is a multilayer coating comprising a plurality of dense thin alternating layers 14a, 14b comprising layers having a low refractive index 14a and a high refractive index 14b. Layers 14a, 14b are stacked on a main surface 16 of substrate 12, along an optical axis A of optical element 10.

The successive layers 14a, 14b have thicknesses, measured along optical axis A, and refractive indices determined so as to minimize the reflected light intensity by means of a destructive interference phenomenon. This type of antireflection offers the benefit of good resistance to environmental conditions, but is limited by the refractive indices of the dense materials that are usable for the thin layers 14a, 14b, as well as by the range of operating wavelengths.

FIG. 2 represents an optical element 20 comprising a transparent substrate 22 and an antireflective coating 24 based on gradient refractive index. Antireflective coating 24 comprises several porous layers 24a, their indices gradually decreasing from substrate 22 along optical axis A, to allow a less abrupt transition between the refractive index of air and that of substrate 22, thus reducing the reflected light intensity.

This type of antireflective coating 24 is obtained using porous layers 24a, the refractive index of porous layer 24a decreasing as the porosity increases. Such porous layers 24a are for example obtained by methods using glancing angle deposition (abbreviated as GLAD) or oblique angle deposition (abbreviated as OAD), which are described in more detail in application FR 3103314 A1.

These coatings 24 have extremely satisfactory optical performances, for the most part explained by the extremely porous layer(s) on the surface, but are very fragile and sensitive to external conditions of temperature, humidity, salinity, and the possible presence of particles in the air. Their use in working optronic devices is therefore very limited.

### PRESENTATION OF THE INVENTION

The invention aims to provide an antireflective coating which benefits from improved properties in comparison to conventional multilayer antireflective coatings, while having satisfactory resistance to environmental conditions.

To this end, the invention relates to an optical element comprising:
a transparent substrate,
an intermediate coating extending over at least one main surface of the substrate, the intermediate coating comprising a plurality of dense thin layers which alternate in having a first refractive index and a second refractive index, the first refractive index being greater than the second refractive index,
characterized in that the optical element also comprises:
at least one porous layer extending over the intermediate coating, opposite the substrate, the porous layer having a third refractive index, the third refractive index being lower than the first and second refractive indices.

The optical element may be, for example, a lens or a porthole.

Such an optical element has improved antireflective properties in comparison to those provided by a conventional multilayer antireflective treatment, while maintaining a satisfactory resistance of the optical element to external conditions as well as a satisfactory appearance.

The term refractive index here is synonymous with that of index of refraction.

The porosity of the porous layer may be between 5% and 70%.

The porosity of a medium is the ratio of the volume not occupied by a solid to the total volume.

The porous layer may be made from a material having a low index, for example such as SiO₂, Al₂O₃, or MgF₂.

The porous layer may comprise elongate elements extending from an external surface of the intermediate coating.

The elongate elements may have dimensions, transverse to their direction of elongation, of between 50 nanometers and 500 nanometers.

The elongate elements may be columns that are substantially rectilinear (of circular or elliptical cross-section) or have helical shapes.

Each elongate element may extend along an axis forming a non-zero angle with a local normal to the external surface of the intermediate coating.

The non-zero angle is for example less than or equal to 50°.

Such angled elongate elements impart a higher porosity to the porous layer.

The porous layer may have a porosity of between 5% and 50%.

The porosity is in particular between 10% and 40%, and more particularly between 15% and 25%.

The invention also relates to an optronic device comprising at least one optical element as above.

The optronic device may comprise in particular a plurality of such optical elements aligned along an optical axis so as to be traversed by a same light beam.

Each optical element may have two main surfaces and be arranged so that the light beam passes through these two main surfaces.

The optronic device may be, for example, a laser rangefinder.

The invention further relates to an aircraft comprising an optronic device as above.

The invention finally relates to a method for manufacturing an optical element as above, comprising steps of:
supplying a substrate and placing the substrate in a deposition device,
depositing thin layers which successively have the first index and the second index, on at least one main surface of the substrate so as to form the intermediate coating,
depositing the porous layer on the intermediate coating, opposite the substrate, using a method of oblique angle deposition.

Such a method makes it possible to produce an optical element as above.

The steps of depositing successive layers of the intermediate coating and of depositing the porous layer may be carried out in the same deposition device, with no loss of vacuum between these two steps.

During the step of depositing the porous layer, an angle of incidence of a deposition beam, measured relative to a local normal to the external surface of the intermediate coating, is between 0° and 80°, and in particular between 40° and 70°.Controlling the angle of incidence allows modifying the porosity of the porous layer.

During the step of depositing the porous layer, the substrate may be kept rotating at a controlled rotation speed about an axis of rotation substantially perpendicular to the external surface.

Controlling the rotation speed allows modifying the shape of the elongate elements of the porous layer.

The rotation speed may be between 0 and 50 revolutions per minute, preferably between 0 and 20 revolutions per minute.

### BRIEF DESCRIPTION OF FIGURES

FIG. 1 is a schematic section view of an optical element of the state of the art, comprising a multilayer antireflective coating based on interference,

FIG. 2 is a schematic section view of a second optical element of the state of the art, comprising an antireflective coating based on gradient refractive index,

FIG. 3 is a schematic section view of an optical element according to the invention, and

FIG. 4 is a set of electron microscopy images of a porous layer of several optical elements according to the invention.

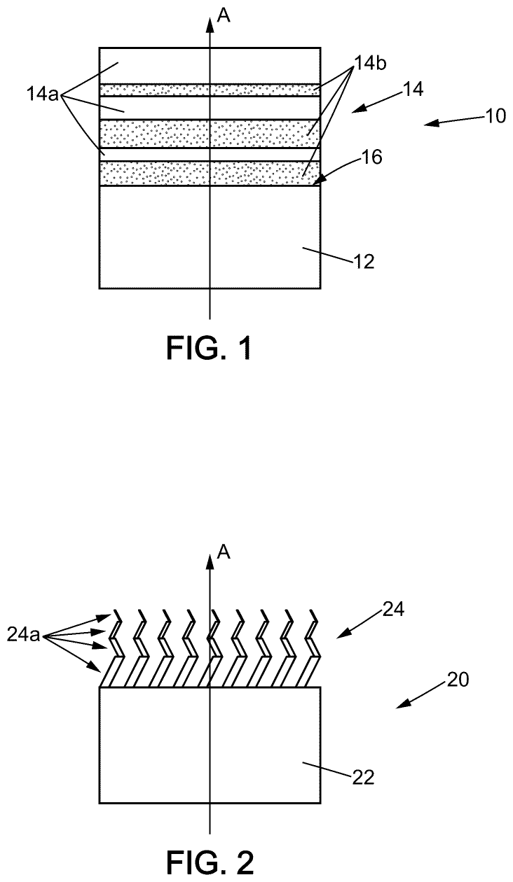

### DETAILED DESCRIPTION OF THE INVENTION

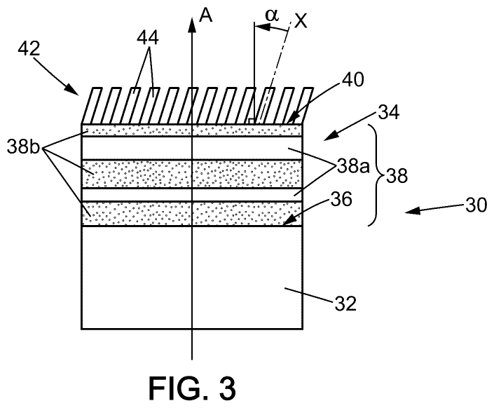

An optical element 30 according to the invention is shown in FIG. 3. Optical element 30 comprises a transparent substrate 32 and an antireflective coating 34 extending over at least one main surface 36 of substrate 32.

Optical element 30 is for example a lens or a porthole, and has a main axis A that is perpendicular to main surface 36. Main axis A is for example the optical axis of element 30, if the element is a lens.

Optical device 30 is intended for example to form part of an optronic device, in particular an optronic device on board an aircraft.

Optical device 30 is preferably an internal element of the optronic device, which is therefore not directly exposed to external conditions. However, optical element 30 is intended to maintain good optical properties over a long period of use in on-board usage conditions.

Substrate 32 is composed of a transparent organic or inorganic material.

Substrate 32 defines main surface(s) 36, which are for example the surface(s) of optical element 30 intended to be traversed by light rays.

Antireflective coating 34 comprises an intermediate coating 38 formed of a plurality of thin layers 38a, 38b stacked along the direction of main axis A on main surface 36, and defining an external surface 40 opposite substrate 32.

Antireflective coating 34 further comprises at least one porous layer 42 extending over external surface 40.

Advantageously, antireflective coating 34 comprises a single porous layer 42, so as to protect the good mechanical resistance of antireflective coating 34.

Thin layers 38a, 38b are dense layers, and comprise layers having a low refractive index 38a and layers having a high refractive index 38b, alternating along the direction of main axis A.

The term “dense” is understood to mean that the layers of intermediate coating 38 have a porosity of less than 5%, and more particularly less than 2%.

Layers 38a having a low refractive index are composed of materials having refractive indices that are preferably less than 1.6.

Layers 38b having a high refractive index are composed of materials having refractive indices that are preferably greater than 1.7, and advantageously greater than 1.9.

Porous layer 42 has a porosity greater than 5%, and preferably less than 60%, in particular less than 40%.

The porous layer has a thickness, measured along axis A, of between 100 nanometers and 1 micrometer.

The refractive index of porous layer 42 decreases when the porosity increases, but sufficient mechanical strength of porous layer 42 is necessary and prevents the use of very high porosities.

Porous layer 42 is formed of a plurality of elongate elements 44, extending from external surface 40.

20 The elongate elements may have diameters, measured in a plane perpendicular to main axis A, of between 50 nanometers and 500 nanometers, depending on the spectral range being targeted for the use of optical element 30.

Elongate elements 44 have the shape of substantially rectilinear columns, as shown in FIG. 3, or of helical columns.

Elongate elements 44 may be substantially perpendicular to external surface 40, or extend along an axis X forming a non-zero angle a with a local normal to external surface 40, as shown in FIG. 3.

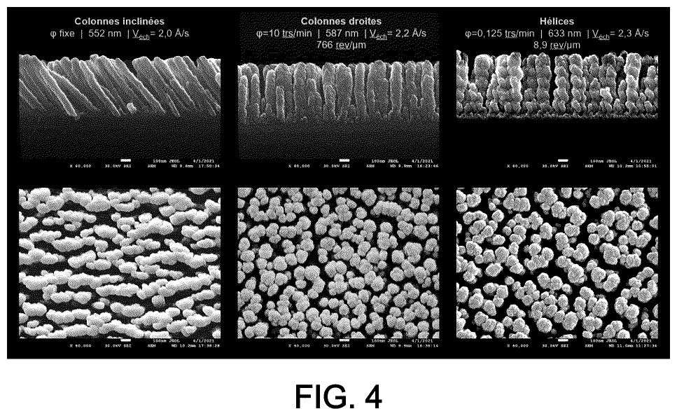

FIG. 4 shows some examples of elongate elements 44, successively in the form of rectilinear columns forming an angle with the normal to external surface 40, in the form of rectilinear columns perpendicular to external surface 40, and in the form of helical columns.

The use of angled elongate elements 44 for porous layer 42 makes it possible to achieve higher porosity values.

The material composing porous layer 42 has a refractive index of between 1.4 and 1.9 in a dense layer, but the porosity of porous layer 42 allows said porous layer to have an index of less than 1.4 and preferably less than 1.3, thus reducing light reflections at the interface with the air.

Such an optical element has antireflective properties over a wide spectral range, for example extending between 400 nanometers and 1800 nanometers in wavelength.

Optical element 30 thus has improved antireflective properties compared to conventional multilayer antireflection while maintaining satisfactory resistance, which is necessary for use in an optronic device carried onboard.

A method for manufacturing optical element 30 will now be described.

The method comprises a preliminary step of supplying substrate 32, and placing said substrate in a deposition chamber, such as the one described in application FR 3103314 A1.

Preferably, all the following steps in the manufacturing method are carried out in the deposition chamber without having to open it, so as to prevent any contamination of the chamber and its contents.

The method comprises a step of depositing intermediate coating 38 on main surface 36, by successive deposition of each of thin layers 38a, 38b. Layers 38a, 38b are deposited under vacuum, from a source for each of the materials composing said layers. The materials are deposited in the form of a deposition beam directed towards main surface 38 at substantially normal incidence. This is understood to mean that the deposition beam is substantially perpendicular to main surface 36.

The method then comprises a step of depositing porous layer 42 on external surface 40 of intermediate coating 38, opposite substrate 32.

Porous layer 42 is deposited using a deposition beam as above, this time at oblique incidence. This is understood to mean that the deposition beam forms a non-zero deposition angle with a local normal to external surface 40. The deposition angle is for example between 40° and 70°.

The oblique angle deposition results in formation of elongate elements 44 which compose porous layer 42 and give it its porosity.

During the deposition of porous layer 42, substrate 32 may be kept fixed or may be rotated about an axis of rotation substantially parallel to main axis A. The porosity of porous layer 44 and the shape of elongate elements 44 may be modified according to the rotation of the substrate.

When substrate 32 is held stationary, elongate elements 44 take the shape of inclined rectilinear columns, as shown in the two images on the left in FIG. 4. This leads to high porosity values for porous layer 42.

When substrate 32 is rotated at high speeds, elongate elements 44 take the shape of rectilinear columns perpendicular to external surface 40, as shown in the middle images of FIG. 4, obtained with a speed of 10 revolutions per minute.

When substrate 32 is rotated at low speeds, elongate elements 44 take the shape of helical columns perpendicular to external surface 40, as shown in the images on the right in FIG. 4, obtained with a speed of 0.125 revolutions per minute.

The deposition rate of porous layer 42 is for example between 0.1 nanometer per second and 1 nanometer per second.

The method described thus makes it possible to manufacture a high-performance optical element 30 in a reliable and repeatable manner, and allows modifying the porosity and the microstructure of porous layer 42 according to the desired results, in a simple manner.

1. An optronic device comprising a plurality of optical elements aligned along an optical axis so as to be passed through by a same light beam, each optical element comprising:
a transparent substrate,
an intermediate coating extending over at least one main surface of the substrate, the intermediate coating comprising a plurality of dense thin layers which alternate in having a first index refractive index and a second refractive index, the first refractive index being greater than the second refractive index, and
at least one porous layer extending over the intermediate coating, opposite the substrate, the porous layer having a third refractive index, the third refractive index being lower than the first and second refractive indices.

2. The optronic device according to claim 1, wherein the porous layer comprises elongate elements extending from an external surface of the intermediate coating.

3. The optronic device according to claim 2, wherein the elongate elements are columns that are rectilinear or have helical shapes.

4. The optronic device according to claim 2, wherein each elongate element extends along an axis (X) forming a non-zero angle (α) with a local normal to the external surface of the intermediate coating.

5. The optronic device according to claim 1, wherein the porous layer has a porosity of between 5% and 50%.

6. An aircraft comprising the optronic device according to claim 1.

7. A method for manufacturing the optical element according to, claim 1, the method comprising steps of:
supplying a substrate and placing the substrate in a deposition device,
depositing thin layers (38a, 38b) which successively have the first index and the second index, on at least one main surface of the substrate as to form the intermediate coating,
depositing the porous layer on an external surface of the intermediate coating, opposite the substrate, using a method of oblique angle deposition.

8. The method according to claim 7, wherein, during the step of depositing the porous layer, an angle of incidence of a deposition beam, measured relative to a local normal to the external surface of the intermediate coating, is between 0° and 80.

9. The method according to claim 8, wherein, during the step of depositing the porous layer, the substrate rotates at a controlled rotation speed about an axis of rotation perpendicular to the external surface.

10. The method according to claim 8, wherein the angle of incidence of the deposition beam is between 40° and 70°.
